(19) United States
(12) Patent Application Publication
(10) Pub. No.: US 2025/0098220 A1
(43) Pub. Date: Mar. 20, 2025

(54) COMPLEMENTARY FIELD EFFECT TRANSISTOR (CFET) CIRCUITS AND METHODS FOR MAKING THE SAME

(71) Applicant: QUALCOMM Incorporated, San Diego, CA (US)

(72) Inventors: Shreesh NARASIMHA, Charlotte, NC (US); Yan SUN, San Diego, CA (US)

(21) Appl. No.: 18/470,207

(22) Filed: Sep. 19, 2023

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 84/0128; H10D 84/0149; H10D 84/038; H10D 84/83

(57) ABSTRACT

Disclosed are complementary field effect transistor (CFET) circuits with vertical routing structures and methods for making the same. In an aspect, a semiconductor structure comprises: a first FET comprising a first source/drain (S/D) region, a second S/D region, and a first gate; a second FET disposed above the first FET and comprising a third S/D region, a fourth S/D region, and a second gate; a frontside metal (FM) layer disposed above the second FET and comprising a set of FM conductors extending in an X direction; and a backside metal (BM) layer disposed below the first FET and comprising a set of BM conductors extending in the X direction. The semiconductor structure also comprises a vertical connector, extending in a Z direction, that electrically couples one of the set of BM conductors to the third S/D region, the fourth S/D region, or the second gate.

### BACKGROUND OF THE DISCLOSURE

### 1. Field of the Disclosure

Aspects of the disclosure relate generally to high performance devices, and more specifically to semiconductor structures for complementary field effect transistors (CFETs).

### 2. Description of the Related Art

Integrated circuit technology has achieved great strides in advancing computing power through miniaturization components such as semiconductor transistors. The progression of semiconductors have progressed from bulk substrates and planar CMOS, FinFETs, nanowires or nanoribbons (also called nanosheets), to nanowire or nanoribbon 3D stacking. The semiconductor technologies have largely been based on silicon. However, fabrication of transistors based on silicon may be problematic when it comes to further reduction in scaling, e.g., to few nanometers. Accordingly, there is a need for systems, apparatus, and methods that overcome the deficiencies of conventional devices including the methods, system and apparatus provided herein.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a semiconductor structure includes a first field effect transistor (FET) of a first charge carrier type, comprising a first source/drain (S/D) region, a second S/D region, and a first gate; a second FET of a second charge carrier type, disposed above the first FET in a Z direction (e.g., a vertical direction) and comprising a third S/D region, a fourth S/D region, and a second gate; a frontside (FS) metal (FM) layer disposed above the second FET in the Z direction and comprising a plurality of FM conductors extending in an X direction (e.g., a first horizontal direction); a backside (BS) metal (BM) layer disposed below the first FET in the Z direction and comprising a plurality of BM conductors extending in the X direction; and a vertical connector extending in the Z direction, wherein the vertical connector electrically couples one of the plurality of BM conductors to the third S/D region, the fourth S/D region, or the second gate.

In an aspect, a method of fabricating a semiconductor structure includes providing a first FET of a first charge carrier type, comprising a first S/D region, a second S/D region, and a first gate; providing a second FET of a second charge carrier type, disposed above the first FET in a Z direction and comprising a third S/D region, a fourth S/D region, and a second gate; providing an FM layer disposed above the second FET in the Z direction and comprising a plurality of FM conductors extending in an X direction and spaced apart from each other in a Y direction (e.g., a second horizontal direction perpendicular to the first horizontal direction); providing a BM layer disposed below the first FET in the Z direction and comprising a plurality of BM conductors extending in the X direction and spaced apart from each other in the Y direction; and providing a vertical connector extending in the Z direction, wherein the vertical connector electrically couples one of the plurality of BM conductors to the third S/D region, the fourth S/D region, or the second gate.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates a nanosheet field effect transistor (FET).

FIG. 2 is a plan view of a conventional standard cell.

FIG. 3 is a cross-sectional view of a conventional monolithic complementary FET (CFET).

FIG. 4A and FIG. 4B show plan views of an example integrated circuit that illustrates a 3T CFET logic cell topology, according to aspects of the disclosure.

FIGS. 4C-4F are cross-sectional views of the integrated circuit in FIGS. 4A and 4B, according to aspects of the disclosure.

FIG. 5A and FIG. 5B show plan views of an example integrated circuit that illustrates a 3T CFET logic cell topology, according to aspects of the disclosure.

FIG. 5C is a cross-section view of the integrated circuit in FIGS. 5A and 5B, according to aspects of the disclosure.

FIG. 6 is a flowchart of an example process for fabricating CFET circuits, according to aspects of the disclosure.

FIG. 7 illustrates a mobile device, according to aspects of the disclosure.

FIG. 8 illustrates various electronic devices that may be integrated with any of the aforementioned devices, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are complementary field effect transistor (CFET) circuits with vertical routing structures and methods for making the same. In an aspect, a semiconductor structure comprises: a first FET of a first charge carrier type comprising a first source/drain (S/D) region, a second S/D region, and a first gate; a second FET of a second charge carrier type disposed above the first FET and comprising a third S/D region, a fourth S/D region, and a second gate; a frontside metal (FM) layer disposed above the second FET and comprising a set of FM conductors extending in an X direction; and a backside metal (BM) layer disposed below the first FET and comprising a set of BM conductors extending in the X direction. The semiconductor structure also comprises a vertical connector, extending in a Z direction, that electrically couples one of the set of BM conductors to the source region, drain region, or gate of the second FET.

The semiconductor structures disclosed herein provide at least the advantage of enabling a highly scaled 3T CFET logic image with sufficient metal layer zero (M0) resources to design efficient logic libraries, enabled by multiple unique middle-of-line (MOL) structural features. These MOL structural features include, but are not limited to, the following: a dense back M0 (BM0) wiring plane; MOL contacts formed on both the front and the back; hybrid backside power connectors, such as a direct backside contact (BSC) for VSS and a deep trench MOL via for VDD (or vice-versa, based on whether the top FET in the CFET is a PFET or an NFET); specialized vertical connectors for the output node (e.g., vertical diffusion to diffusion contacts); and horizontal diffusion to diffusion contacts referred to herein as backside jumpers (BSJs).

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

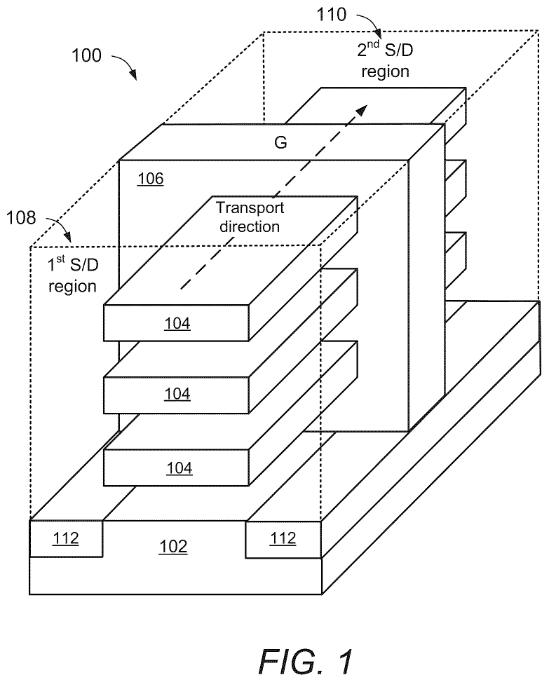

FIG. 1 illustrates a nanosheet field effect transistor (FET) 100. The nanosheet FET 100 shown in FIG. 1 is built upon a silicon substrate 102 and comprises a set of three nanosheets 104 that extend through a gate-all-around gate (GAA) structure 106. One end of the three nanosheets 104 are electrically connected together in a first epitaxial (EPI) structure (not shown) to form a first source/drain (S/D) region 108, and the other end of the three nanosheets 104 are electrically connected together in a second EPI structure (also not shown) to form a second S/D region 110. The gate structure is isolated from the substrate 102 by oxide isolation regions 112. The structure can be adapted so that the substrate 102 is removed entirely, to facilitate backside connectivity. The nanosheets 104 are the channels by which the charge carrier travels through the GAA structure 106 to get from the first S/D region 108 to the second S/D region 110, and thus may be referred to herein as “nanosheet channels”. Although not shown in FIG. 1 for simplicity, the nanosheets 104 are electrically insulated from the GAA structure 106 by a dielectric layer that surrounds the portions of the nanosheets 104 that go through the GAA structure 106.

For each pair of S/D regions on either side of a gate, one S/D region may operate as the source and the other S/D region may operate as the drain, or vice-versa. Generally, the term “source” is used to refer to the S/D region that is tied to the source of the charge carrier (i.e., for a PFET, the S/D region tied to VDD; for an NFET, the S/D region tied to VSS), and thus whether the first S/D region 108 or the second S/D region 110 is the source depends on the specific electrical connection made to each.

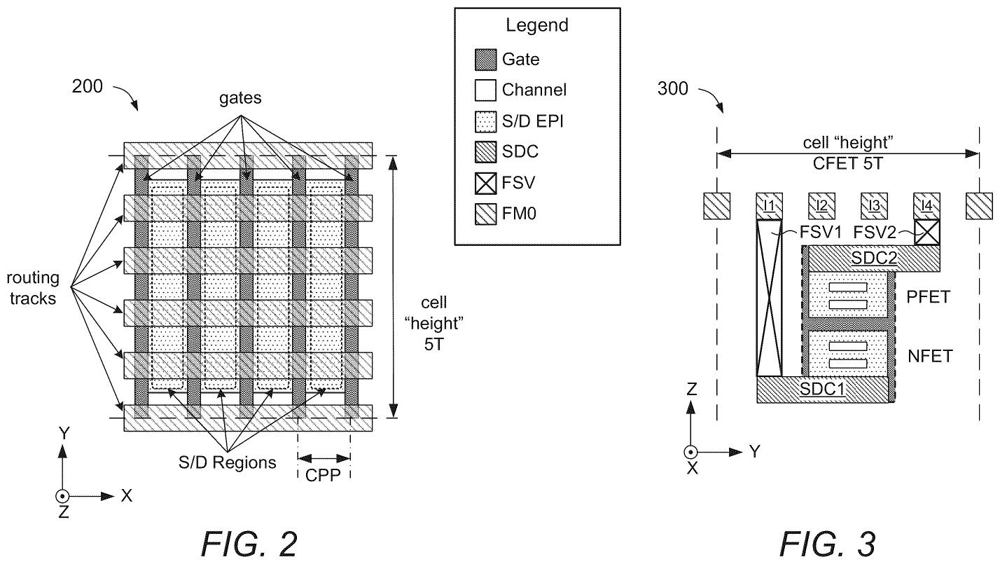

FIG. 2 is a plan view of a conventional standard cell 200 having gates extending along a Y direction and spaced apart from each other along an X direction and having frontside routing tracks extending along the X direction and spaced apart from each other along the Y direction. Contacted poly pitch (CPP) is the distance separating the centers of adjacent gates. The standard cell shown in FIG. 2 is “track-aligned”, meaning that routing tracks at the top and bottom of the figure are shared with standard cells adjacent to the cell 200 in the Y direction and are typically used for power and ground. The cell 200 shown in FIG. 2 is a “5T” cell, which has four internal routing tracks, where “internal” refers to the fact that they are between the routing tracks at the top and bottom of the figure and are used for routing between structures internal to the standard cell (rather than being power and ground buses). As shown in FIG. 2, an EPI structure, which may also be referred to herein as an EPI layer, occupies the space between the gates, and forms a set of S/D regions, one on each side of a gate. As such, an S/D region may also be referred to herein as an S/D EPI region. The location of the EPI structure and the S/D regions within is illustrative.

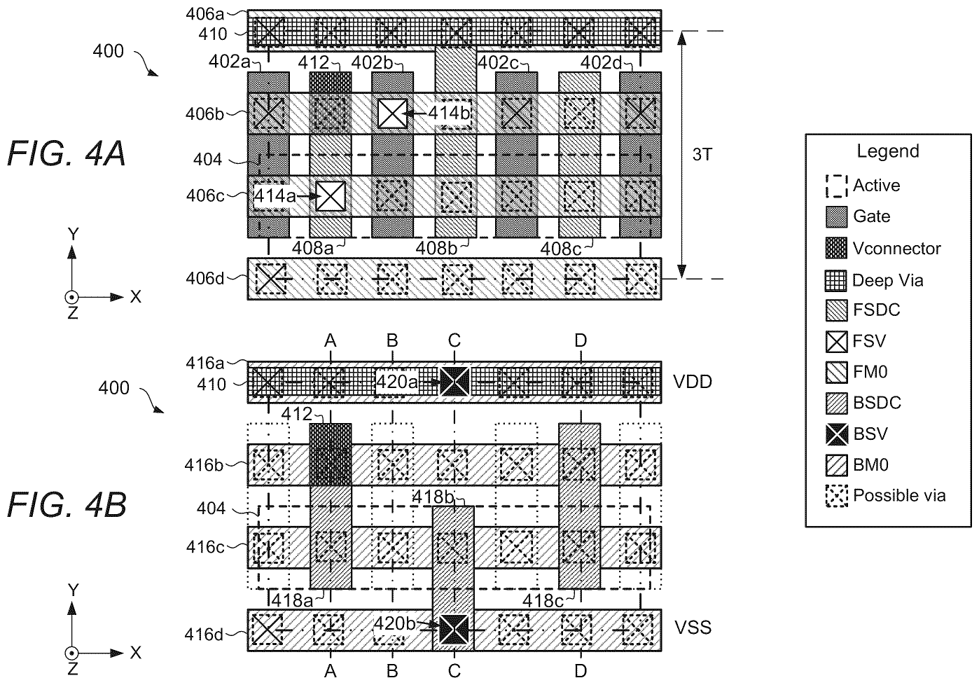

FIG. 3 is a cross-sectional view of a conventional monolithic complementary FET (CFET) 300 comprising a pair of nanosheet FETs stacked vertically. FIG. 3 illustrates a cross section though the gate structure, where the current goes into or out of the page, depending on the charge carrier. In the example shown in FIG. 3, the CFET 300 includes a nanosheet p-channel FET structure (PFET) above a nanosheet n-channel FET structure (NFET) in a Z direction. The four frontside internal routing tracks are labeled I1 through I4. A first frontside via, FSV1, electrically couples routing track I1 to a first source/drain (S/D) contact (SDC), SDC1. A second frontside via, FSV2, electrically couples routing track I4 to a second S/D contact, SDC2. FIG. 3 illustrates a disadvantage of the design of CFET 300, namely, that because the bottom FET in the vertical CFET stack—an NFET in the case of CFET 300—must have an electrical connection to a frontside routing track, this means that there are fewer internal routing tracks available for making other internal connections within a standard cell, which raises the minimum number of internal tracks needed to successfully route circuits within a complex standard cell. In FIG. 3, for example, complex standard cells using frontside-only routing tracks must have at least four internal routing tracks, which means that the cell must be at least a 5T or 6T design rather than a 4T or 3T design. To use less than four internal routing tracks would require the cell to expand in the X direction to accommodate internal connections, would require the use of higher-level metal structures above the standard cell to electrically couple internal structures of the standard cell to each other, or both-thus negating the potential advantages of a cell height reduction.

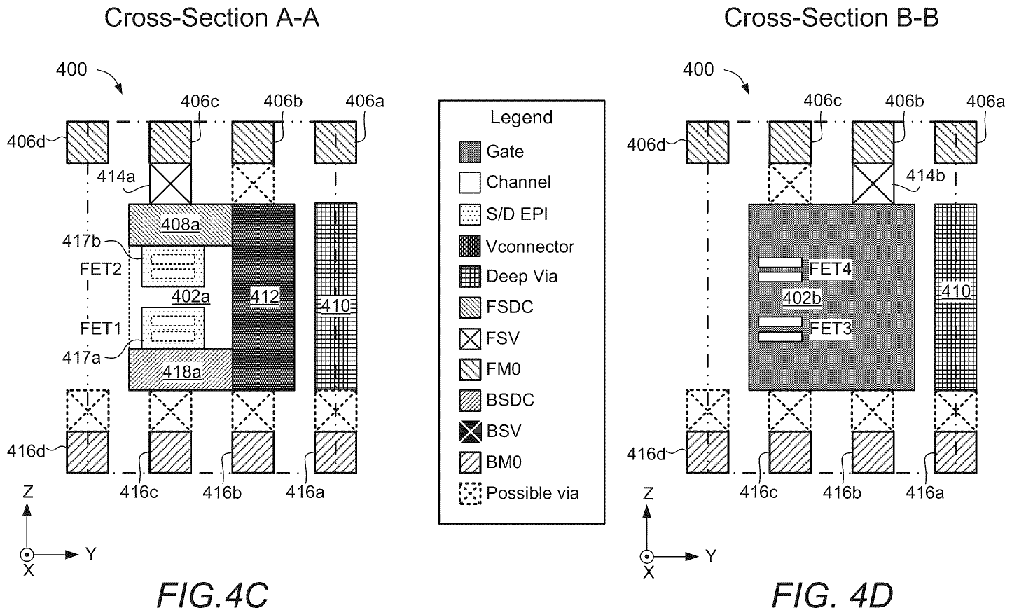

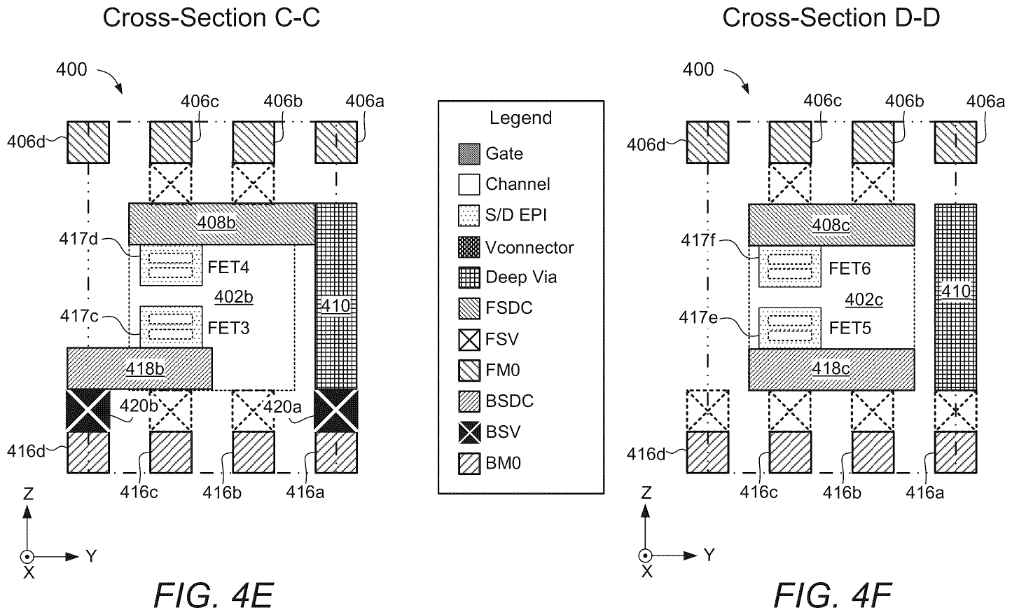

FIG. 4A and FIG. 4B show plan views of an example integrated circuit 400 that illustrates a 3T CFET logic cell topology, according to aspects of the disclosure. These figures are intended to illustrate topology and connectivity. They are not intended to illustrate any specific logic function. FIG. 4A shows the frontside connections of the integrated circuit 400, as seen from the frontside, and FIG. 4B shows the backside connections of the integrated circuit 400, also as seen from the frontside. Unless otherwise specified, dashed shapes in FIG. 4B correspond to like-located frontside structures that may be accessed during the backside process for creating electrical connections. It is noted that the same architectural features are not limited to 3T topologies, but may also be applied to 2T, 4T, or other topologies.

In the example shown in FIG. 4A and FIG. 4B, the integrated circuit 400 includes a set of gate structures, labeled 402a through 402d, extending in the Y direction and spaced apart from each other in the X direction, which may be herein referred to collectively as gates 402 and individually as gate 402a, gate 402b, etc.

In the example shown in FIG. 4A and FIG. 4B, the integrated circuit 400 also includes an active region 404. Within the active region, the gates 402 contain channels that extend in the X direction through the gate structures and that electrically couple to source/drain (S/D) structures on either side of the gate structures. In some aspects, the S/D structures comprise epitaxial (EPI) layers.

In the example shown in FIG. 4A, the integrated circuit 400 includes a set of frontside (FS) routing tracks, labeled 406a through 406d, extending in the X direction and spaced apart from each other in the Y direction, which may be herein referred to collectively as FS tracks 406 and individually as FS track 406a, FS track 406b, etc. In some aspects, each FS routing track may comprise an FS metal-zero (FM0) conductor. The integrated circuit 400 also includes a set of frontside source/drain contacts (FSDCs), labeled 408a through 408c, which may be herein referred to collectively as FSDCs 408 and individually as FSDC 408a, FSDC 408b, etc. The integrated circuit 400 also includes a deep trench via 410 and a vertical connector 412. In some aspects, the vertical connector 412 may be used to from an output connector. The integrated circuit 400 also includes a set of frontside vias (FSVs), labeled 414a and 414b, which may be herein referred to collectively as FSVs 414 and individually as FSV 414a, FSV 414b, etc.

In the example shown in FIG. 4B, the integrated circuit 400 includes a set of backside (BS) routing tracks, labeled 416a through 416d, extending in the X direction and spaced apart from each other in the Y direction, which may be herein referred to collectively as BS tracks 416 and individually as BS track 416a, BS track 416b, etc. In some aspects, each BS routing track may comprise an BS metal-zero (BM0) conductor. The BS tracks 416 provide a dense BM0 contact plane, shown in FIG. 4B as having the same pitch as the FM0 contact plane, but in other aspects may have a different pitch than the FM0 contact plane. The integrated circuit 400 also includes a set of backside source/drain contacts (BSDCs), labeled 418a through 418c, which may be herein referred to collectively as BSDCs 418 and individually as BSDC 418a, BSDC 418b, etc. The integrated circuit 400 also includes a set of backside vias (BSVs), labeled 420a and 420b, which may be herein referred to collectively as BSVs 420 and individually as BSV 420a, BSV 420b, etc. FIG. 4B includes markings to show the locations of cross-sections A-A, B-B, C-C, and D-D.

FIGS. 4A and 4B also include markings to show some possible locations of other FSVs and BSVs, but it is noted that the possible locations of other vias are illustrative and not limiting. It will be understood that the many possible via locations provide many “hit points” for easy connectivity to gates, diffusions, and output nodes, which provides high connection flexibility and the possibility of dense internal routing, all of which allow complex standard cells to be constructed within the constraints imposed by a 3T design profile.

FIG. 4C is a cross-sectional view of integrated circuit 400 along cut line A-A, according to aspects of the disclosure. FIG. 4C shows the relative locations of gate 402a, FS tracks 406a-d, FSDC 408a, deep trench via 410, vertical connector 412, FSV 414a, BS tracks 416a-d, and BSDC 418a. As seen in FIG. 4C, gate 402a, which is a gate-all-around (GAA) gate structure, includes stacks of nanosheet channels that make up a bottom FET and a top FET, labeled FET1 and FET2, respectively. FIG. 4C shows a first S/D region 417a associated with FET1 and a second S/D region 417b associated with FET2. In this image, the gate 402a as well as the nanosheet channels of FET1 and FET2 are out of the plane of the cross section, and so these are depicted with dotted outlines. Similarly, elements that are optional (and included for instructive purposes), such as the locations of the possible vias, are also depicted with dotted lines. As shown in FIG. 4C, the vertical connector 412 provides an electrical connection between the S/D region 417a of FET1 and the S/D region 417b of FET2 by way of the FSDC 408a and the BSDC 418a. In some aspects, FET1 may be NFET and FET2 may be an PFET (or vice-versa) of a CFET pair. In some aspects, the CFET pair comprising FET1 and FET2 may be two parts of an inverter, in which case the vertical connector 412 may be the output of the inverter. In FIG. 4C, this output is connected to FS track 406c via FSV 414a, may instead or additionally be connected to FS track 406b, BS track 416b, BS track 416c, etc., using the possible vias shown in FIG. 4C. In this figure and other figures that show possible via locations, it is noted that the example locations shown are illustrative and not limiting.

FIG. 4D is a cross-sectional view of integrated circuit 400 along cut line B-B, according to aspects of the disclosure. FIG. 4D shows the relative locations of gate 402b, FS tracks 406a-d, deep trench via 410, FSV 414b, and BS tracks 416a-d. As seen in FIG. 4D, gate 402b includes channels that make up a bottom FET and a top FET, labeled FET3 and FET4, respectively. In FIG. 4D, the gate is connected to FS track 406b via FSV 414b, but may instead or additionally be connected to FS track 406c, BS track 416b, BS track 416c, etc., using the possible vias shown in FIG. 4D.

FIG. 4E is a cross-sectional view of integrated circuit 400 along cut line C-C, according to aspects of the disclosure. FIG. 4E shows the relative locations of gate 402b, FS tracks 406a-d, FSDC 408b, deep trench via 410, BS tracks 416a-d, BSDC 418b, and BSV 402a-b. FIG. 4E shows a third S/D region 417c associated with FET3 and a fourth S/D region 417d associated with FET4. As seen in FIG. 4E, gate 402b includes the channels of FET3 and FET4, which are out of the plane of the cross-section. In this image, the gate 402b as well as FET3 and FET4 are out of the plane of the cross section, and so these are depicted with dotted outlines. As shown in FIG. 4E, the FSDC 408b electrically couples the source of FET4 to the deep trench via 410, which is connected to the BS track 416a by way of BSV 420a. The BSDC 418b electrically couples the source of FET3 to the BS track 416d by way of the BSV 420b. In some aspects, FET4 may be PFET and FET3 may be an NFET (or vice-versa) of a CFET pair. In some aspects, the CFET pair comprising FET3 and FET4 may be two parts of an inverter, in which case the BS track 416a may supply VDD to the source of FET4 and the BS track 416d may supply VSS to the source of FET3.

FIG. 4F is a cross-sectional view of integrated circuit 400 along cut line D-D, according to aspects of the disclosure. FIG. 4F shows the relative locations of gate 402c, FS tracks 406a-d, deep trench via 410, BS tracks 416a-d, and BSDC 418c. FIG. 4F shows a fifth S/D region 417e associated with FET5 and a sixth S/D region 417f associated with FET6. As seen in FIG. 4F, gate 402c includes channels that make up a bottom FET and a top FET, labeled FET5 and FET6, respectively, which are out of the plane of the cross-section. In this image, the gate 402c as well as FET5 and FET6 are out of the plane of the cross section, and so these are depicted with dotted outlines. FIG. 4F illustrates the point that FET6 may be connected to FS track 406b and/or FS track 406c and that FET5 may be connected to BS track 416b and/or BS track 416c.

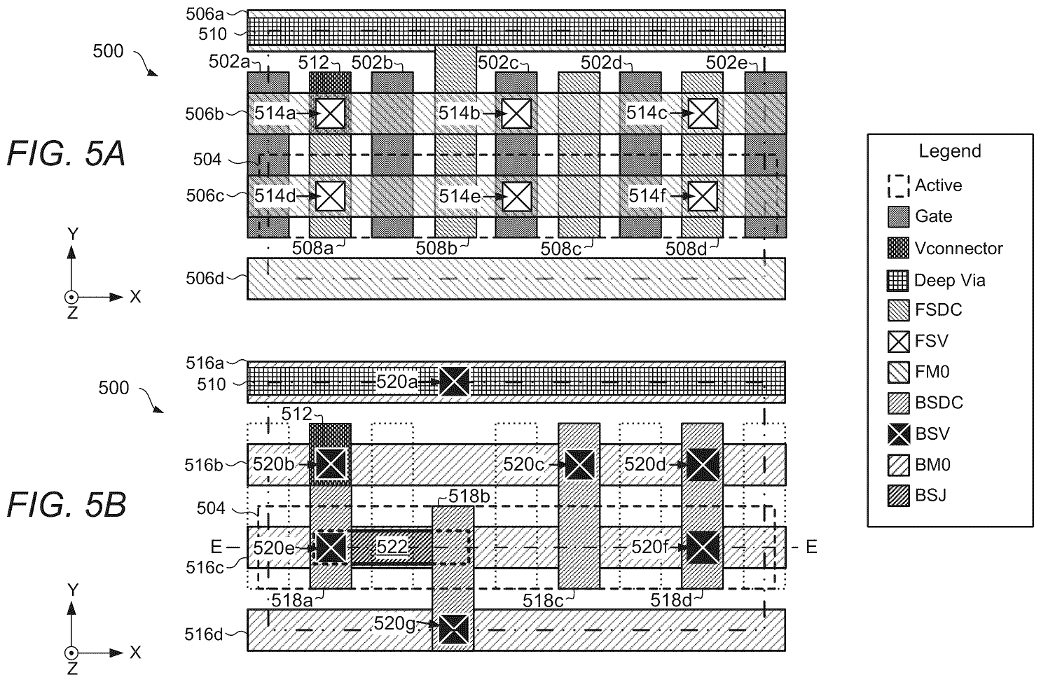

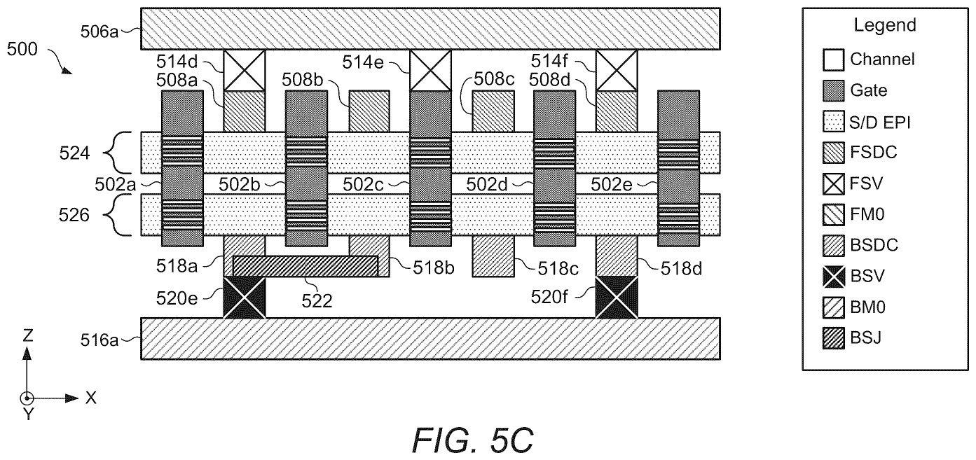

FIG. 5A and FIG. 5B show plan views of an example integrated circuit 500 that illustrates a 3T CFET logic cell topology, according to aspects of the disclosure. These figures are intended to illustrate topology and connectivity. They are not intended to illustrate any specific logic function. FIG. 5A shows the frontside connections of the integrated circuit 500, as seen from the frontside, and FIG. 5B shows the backside connections of the integrated circuit 50, also as seen from the frontside. Unless otherwise specified, dashed shapes in FIG. 5B correspond to like-located frontside structures that may be accessed during the backside process for creating electrical connections. It is noted that the same architectural features are not limited to 3T topologies, but may also be applied to 2T, 4T, or other topologies.

In the example shown in FIG. 5A and FIG. 5B, the integrated circuit 500 includes a set of gate structures, labeled 502a through 502e, extending in the Y direction and spaced apart from each other in the X direction, which may be herein referred to collectively as gates 502 and individually as gate 502a, gate 502b, etc.

In the example shown in FIG. 5A and FIG. 5B, the integrated circuit 500 also includes an active region 504. Within the active region, the gates 502 contain channels that extend in the X direction through the gate structures and that electrically couple to S/D structures on either side of the gate structures. In some aspects, the S/D structures comprise EPI layers.

In the example shown in FIG. 5A, the integrated circuit 500 includes a set of FS routing tracks, labeled 506a through 506d, extending in the X direction and spaced apart from each other in the Y direction, which may be herein referred to collectively as FS tracks 506 and individually as FS track 506a, FS track 506b, etc. In some aspects, each FS routing track may comprise an FM0 conductor. The integrated circuit 500 also includes a set of FSDCs, labeled 508a through 508d, which may be herein referred to collectively as FSDCs 508 and individually as FSDC 508a, FSDC 508b, etc. The integrated circuit 500 also includes a deep trench via 510 and a vertical connector 512. The integrated circuit 500 also includes a set of FSVs, labeled 514a through 514f, which may be herein referred to collectively as FSVs 514 and individually as FSV 514a, FSV 514b, etc.

In the example shown in FIG. 5B, the integrated circuit 500 includes a set of backside (BS) routing tracks, labeled 516a through 516d, extending in the X direction and spaced apart from each other in the Y direction, which may be herein referred to collectively as BS tracks 516 and individually as BS track 516a, BS track 516b, etc. In some aspects, each BS routing track may comprise an BM0 conductor. The integrated circuit 500 also includes a set of BSDCs, labeled 518a through 518d, which may be herein referred to collectively as BSDCs 518 and individually as BSDC 518a, BSDC 518b, etc. The integrated circuit 500 also includes a set of BSVs, labeled 520a through 520g, which may be herein referred to collectively as BSVs 520 and individually as BSV 520a, BSV 520b, etc. The integrated circuit 500 also includes a backside jumper (BSJ) 522, which provides a bidirectional local interconnect. FIG. 5B includes markings to show the location of cross-section E-E.

FIG. 5C is a cross-sectional view of integrated circuit 500 along cut line E-E, according to aspects of the disclosure. FIG. 5C shows the relative locations of gates 502a-e, FS track 506a, FSDCs 508a-d, FSVs 514d-f, BS track 516a, BSDCs 518a-d, BSVs 520e-f, and the BSJ 522. FIG. 5C also shows the relative locations of a top EPI layer 524 and a bottom EPI layer 526. As shown in FIG. 5C, each of the gates 502 include sets of channels that extend in the X direction and that are separated from each other along the Z direction. A first set of channels electrically couples regions of the top EPI layer 524 to each other through the respective gate. A second set of channels electrically couples regions of the bottom EPI layer 526 to each other through the respective gate. In some aspects, FETs within the top EPI layer 524 are PFETs and FETs within the bottom EPI layer 526 are NFETs (or vice-versa). As shown in FIG. 5C, the BSJ 522 electrically couples BSDC 518a to BSDC 518b but does not make contact with the bottom of gate 502b.

It is noted that while the integrated circuit 500 has six FSVs 514 and seven BSVs 520, the number of possible vias, omitted in FIGS. 5A-5C for clarity, may be much larger, e.g., such as shown in FIGS. 4A and 4B. For example, in FIG. 5C, a FSV may be placed above each gate 502 and FSDC 508, and a BSV may be placed below each gate 502 and BSDC 518.

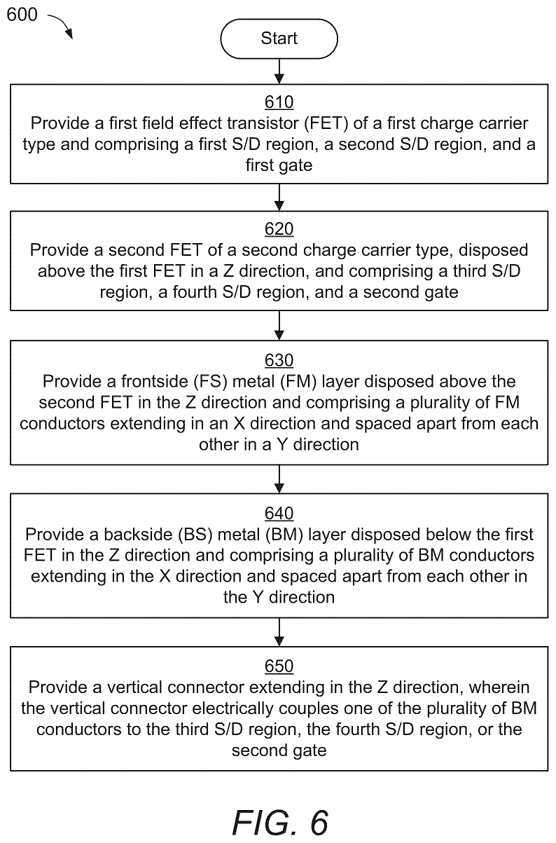

FIG. 6 is a flowchart of an example process 600 for fabricating CFET circuits, according to aspects of the disclosure.

As shown in FIG. 6, process 600 may comprise, at 610, providing a first FET of a first charge carrier type, comprising a first S/D region, a second S/D region, and a first gate.

As shown in FIG. 6, process 600 may comprise, at 620, providing a second FET of a second charge carrier type, disposed above the first FET in a Z direction and comprising a third S/D region disposed above the first S/D region, a fourth S/D region disposed above the second S/D region, and a second gate disposed above the first gate.

As shown in FIG. 6, process 600 may comprise, at 630, providing a frontside FM layer disposed above the second FET in the Z direction and comprising a plurality of FM conductors extending in the X direction and spaced apart from each other in the Y direction.

As shown in FIG. 6, process 600 may comprise, at 640, providing a BM layer disposed below the first FET in the Z direction and comprising a plurality of BM conductors extending in the X direction and spaced apart from each other in the Y direction.

As shown in FIG. 6, process 600 may comprise, at 650, providing a vertical connector extending in the Z direction, wherein the vertical connector electrically couples one of a plurality of BM conductors to the third S/D region, the fourth S/D region, or the second gate.

In some aspects, providing the first FET comprises providing a gate-all-around (GAA) FET comprising a first GAA region and wherein providing the second FET comprises providing a GAA FET comprising a second GAA region.

In some aspects, providing the first FET comprises providing a first plurality of nanosheet channels extending in the X direction and spaced apart from each other in the Z direction to from a first vertical stack, each channel electrically coupling the first S/D region to the second S/D region through the first GAA region and being separated from the first GAA region by a first dielectric material, and providing the second FET comprises providing a plurality of nanosheet channels extending in the X direction and spaced apart from each other in the Z direction to from a second vertical stack disposed above the first vertical stack in the Z direction, each channel electrically coupling the third S/D region to the fourth S/D region through the second GAA region, each nanosheet being separated from the second GAA region by a second dielectric material.

In some aspects, providing the vertical connector comprises providing the vertical connector as a trench via extending in the X direction.

In some aspects, providing the vertical connector comprises providing a vertical connector that extends in the Z direction at least from a bottom surface of the first gate to a top surface of the second gate.

In some aspects, process 600 further comprises providing a second vertical connector that electrically couples the second S/D region to the fourth S/D region by direct contact with both the second S/D region and the fourth S/D region.

In some aspects, process 600 further comprises electrically coupling the second vertical connector to another of the plurality of FM conductors, another of the plurality of BM conductors, or both.

In some aspects, process 600 further comprises providing a backside jumper (BSJ), disposed below the first gate and isolated from the first gate by a dielectric material, that electrically couples the first S/D region to the second S/D region.

In some aspects, process 600 further comprises electrically coupling the BSJ to another of the plurality of BM conductors.

In some aspects, the plurality of FM conductors extending in the X direction consists of four or fewer FM conductors extending in the X direction.

In some aspects, the plurality of BM conductors extending in the X direction consists of four or fewer BM conductors extending in the X direction.

In some aspects, the plurality of FM conductors extending in the X direction consists of three or fewer FM conductors extending in the X direction.

In some aspects, the plurality of BM conductors extending in the X direction consists of three or fewer BM conductors extending in the X direction.

Process 600 may include additional implementations, such as any single implementation or any combination of implementations described above and/or in connection with one or more other processes described elsewhere herein. Although FIG. 6 shows example blocks of process 600, in some implementations, process 600 may include additional blocks, fewer blocks, different blocks, or differently arranged blocks than those depicted in FIG. 6. Additionally, or alternatively, two or more of the blocks of process 600 may be performed in parallel.

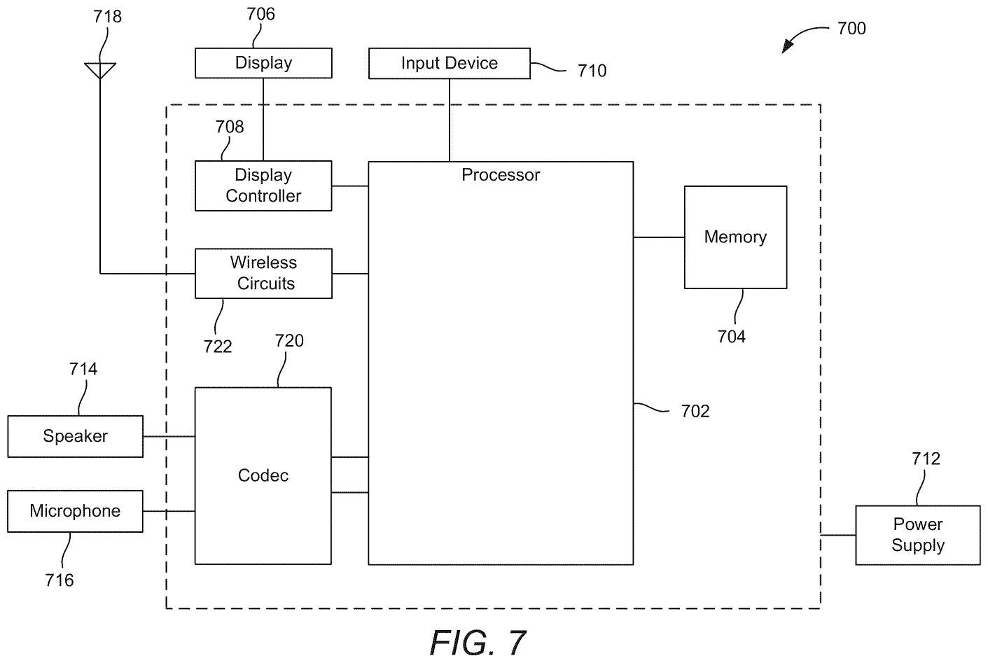

FIG. 7 illustrates a mobile device 700, according to aspects of the disclosure. In some aspects, the mobile device 700 may be implemented by including one or more IC devices manufactured based on the examples described in this disclosure.

In some aspects, mobile device 700 may be configured as a wireless communication device. As shown, mobile device 700 includes processor 702. Processor 702 may be communicatively coupled to memory 704 over a link, which may be a die-to-die or chip-to-chip link. Mobile device 700 also includes display 706 and display controller 708, with display controller 708 coupled to processor 702 and to display 706. The mobile device 700 may include input device 710 (e.g., physical, or virtual keyboard), power supply 712 (e.g., battery), speaker 714, microphone 716, and wireless antenna 718. In some aspects, the power supply 712 may directly or indirectly provide the supply voltage for operating some or all of the components of the mobile device 700.

In some aspects, FIG. 7 may include coder/decoder (CODEC) 720 (e.g., an audio and/or voice CODEC) coupled to processor 702; speaker 714 and microphone 716 coupled to CODEC 720; and wireless circuits 722 (which may include a modem, RF circuitry, filters, etc.) coupled to wireless antenna 718 and to processor 702.

In some aspects, one or more of processor 702, display controller 708, memory 704, CODEC 720, and wireless circuits 722 may include one or more IC devices including semiconductor structures manufactured according to the examples described in this disclosure.

It should be noted that although FIG. 7 depicts a mobile device 700, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

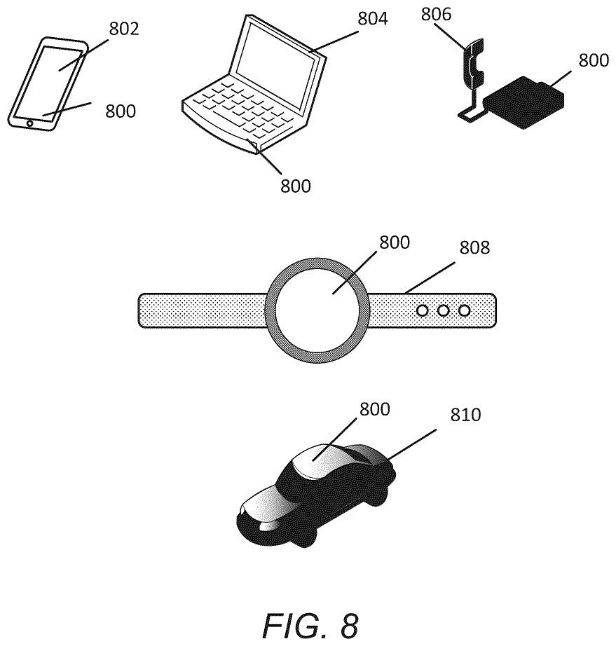

FIG. 8 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (POP), System in Package (SiP), or System on Chip (SoC). For example, a mobile phone device 802, a laptop computer device 804, a fixed location terminal device 806, a wearable device 808, or automotive vehicle 810 may include a semiconductor device 800 (which may include integrated circuits 400 and 500) as described herein. The devices 802, 804, 806 and 808 and the vehicle 810 illustrated in FIG. 8 are merely exemplary. Other apparatuses or devices may also feature the semiconductor device 800 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A semiconductor structure, comprising: a first field effect transistor (FET) of a first charge carrier type, comprising a first source/drain (S/D) region, a second S/D region, and a first gate; a second FET of a second charge carrier type, disposed above the first FET in a Z direction and comprising a third S/D region, a fourth S/D region, and a second gate; a frontside (FS) metal (FM) layer disposed above the second FET in the Z direction and comprising a plurality of FM conductors extending in an X direction; a backside (BS) metal (BM) layer disposed below the first FET in the Z direction and comprising a plurality of BM conductors extending in the X direction; and a vertical connector extending in the Z direction, wherein the vertical connector electrically couples one of the plurality of BM conductors to the third S/D region, the fourth S/D region, or the second gate.

Clause 2. The semiconductor structure of clause 1, wherein the first gate comprises a first gate-all-around (GAA) structure comprising a first GAA region and wherein the second gate comprises a second GAA structure comprising a second GAA region.

Clause 3. The semiconductor structure of clause 2, wherein: the first FET comprises a first plurality of nanosheet channels extending in the X direction and spaced apart from each other in the Z direction to from a first vertical stack, each channel electrically coupling the first S/D region to the second S/D region through the first GAA region and being separated from the first GAA region by a first dielectric material; and the second FET comprises a second plurality of nanosheet channels extending in the X direction and spaced apart from each other in the Z direction to from a second vertical stack disposed above the first vertical stack in the Z direction, each channel electrically coupling the third S/D region to the fourth S/D region through the second GAA region and being separated from the second GAA region by a second dielectric material.

Clause 4. The semiconductor structure of any of clauses 1 to 3, wherein the vertical connector provides a first voltage from the one of the plurality of BM conductors to the third S/D region, the fourth S/D region, or the second gate.

Clause 5. The semiconductor structure of any of clauses 1 to 4, wherein the vertical connector comprises a trench via extending in the X direction.

Clause 6. The semiconductor structure of any of clauses 1 to 5, wherein the vertical connector extends in the Z direction at least from a bottom surface of the first gate to a top surface of the second gate.

Clause 7. The semiconductor structure of any of clauses 1 to 6, further comprising a second vertical connector that electrically couples the second S/D region to the fourth S/D region by direct contact with both the second S/D region and the fourth S/D region.

Clause 8. The semiconductor structure of clause 7, wherein the second vertical connector is electrically coupled to one of the plurality of FM conductors, another of the plurality of BM conductors, or both.

Clause 9. The semiconductor structure of any of clauses 1 to 8, further comprising a backside jumper (BSJ), disposed below the first gate and isolated from the first gate by a dielectric material, that electrically couples the first S/D region to the second S/D region.

Clause 10. The semiconductor structure of clause 9, wherein the BSJ is electrically connected to another of the plurality of BM conductors.

Clause 11. The semiconductor structure of any of clauses 1 to 10, wherein the semiconductor structure comprises a standard cell.

Clause 12. The semiconductor structure of clause 11, wherein the plurality of FM conductors extending in the X direction consists of four or fewer FM conductors extending in the X direction.

Clause 13. The semiconductor structure of any of clauses 11 to 12, wherein the plurality of BM conductors extending in the X direction consists of four or fewer BM conductors extending in the X direction.

Clause 14. The semiconductor structure of clause 11, wherein the plurality of FM conductors extending in the X direction consists of three or fewer FM conductors extending in the X direction.

Clause 15. The semiconductor structure of any of clauses 11 and 14, wherein the plurality of BM conductors extending in the X direction consists of three or fewer BM conductors extending in the X direction.

Clause 16. A method of fabricating a semiconductor structure, the method comprising: providing a first FET of a first charge carrier type, comprising a first S/D region, a second S/D region, and a first gate; providing a second FET of a second charge carrier type, disposed above the first FET in a Z direction and comprising a third S/D region, a fourth S/D region, and a second gate; providing a frontside (FS) metal (FM) layer disposed above the second FET in the Z direction and comprising a plurality of FM conductors extending in an X direction and spaced apart from each other in a Y direction; providing a backside (BS) metal (BM) layer disposed below the first FET in the Z direction and comprising a plurality of BM conductors extending in the X direction and spaced apart from each other in the Y direction; and providing a vertical connector extending in the Z direction, wherein the vertical connector electrically couples one of the plurality of BM conductors to the third S/D region, the fourth S/D region, or the second gate.

Clause 17. The method of clause 16, wherein providing the first FET comprises providing a gate-all-around (GAA) FET comprising a first GAA region and wherein providing the second FET comprises providing a GAA FET comprising a second GAA region.

Clause 18. The method of clause 17, wherein: providing the first FET comprises providing a first plurality of nanosheet channels extending in the X direction and spaced apart from each other in the Z direction to from a first vertical stack, each channel electrically coupling the first S/D region to the second S/D region through the first GAA region and being separated from the first GAA region by a first dielectric material; and providing the second FET comprises providing a plurality of nanosheet channels extending in the X direction and spaced apart from each other in the Z direction to from a second vertical stack disposed above the first vertical stack in the Z direction, each channel electrically coupling the third S/D region to the fourth S/D region through the second GAA region and being separated from the second GAA region by a second dielectric material.

Clause 19. The method of any of clauses 16 to 18, wherein providing the vertical connector comprises providing the vertical connector as a trench via extending in the X direction.

Clause 20. The method of any of clauses 16 to 19, wherein providing the vertical connector comprises providing a vertical connector that extends in the Z direction at least from a bottom surface of the first gate to a top surface of the second gate.

Clause 21. The method of any of clauses 16 to 20, further comprising providing a second vertical connector that electrically couples the second S/D region to the fourth S/D region by direct contact with both the second S/D region and the fourth S/D region.

Clause 22. The method of clause 21, further comprising electrically coupling the second vertical connector to one of the plurality of FM conductors, another of the plurality of BM conductors, or both.

Clause 23. The method of any of clauses 16 to 22, further comprising providing a backside jumper (BSJ), disposed below the first gate and isolated from the first gate by a dielectric material, that electrically couples the first S/D region to the second S/D region.

Clause 24. The method of clause 23, further comprising electrically coupling the BSJ to another of the plurality of BM conductors.

Clause 25. The method of any of clauses 16 to 24, wherein the plurality of FM conductors extending in the X direction consists of four or fewer FM conductors extending in the X direction.

Clause 26. The method of any of clauses 16 to 25, wherein the plurality of BM conductors extending in the X direction consists of four or fewer BM conductors extending in the X direction.

Clause 27. The method of any of clauses 16 to 24, wherein the plurality of FM conductors extending in the X direction consists of three or fewer FM conductors extending in the X direction.

Clause 28. The method of any of clauses 16 to 24 and 27, wherein the plurality of BM conductors extending in the X direction consists of three or fewer BM conductors extending in the X direction.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A semiconductor structure, comprising:
a first field effect transistor (FET) of a first charge carrier type, comprising a first source/drain (S/D) region, a second S/D region, and a first gate;
a second FET of a second charge carrier type, disposed above the first FET in a Z direction and comprising a third S/D region, a fourth S/D region, and a second gate;
a frontside (FS) metal (FM) layer disposed above the second FET in the Z direction and comprising a plurality of FM conductors extending in an X direction;
a backside (BS) metal (BM) layer disposed below the first FET in the Z direction and comprising a plurality of BM conductors extending in the X direction; and
a vertical connector extending in the Z direction, wherein the vertical connector electrically couples one of the plurality of BM conductors to the third S/D region, the fourth S/D region, or the second gate.

2. The semiconductor structure of claim 1, wherein the first gate comprises a first gate-all-around (GAA) structure comprising a first GAA region and wherein the second gate comprises a second GAA structure comprising a second GAA region.

3. The semiconductor structure of claim 2, wherein:
the first FET comprises a first plurality of nanosheet channels extending in the X direction and spaced apart from each other in the Z direction to from a first vertical stack, each channel electrically coupling the first S/D region to the second S/D region through the first GAA region and being separated from the first GAA region by a first dielectric material; and
the second FET comprises a second plurality of nanosheet channels extending in the X direction and spaced apart from each other in the Z direction to from a second vertical stack disposed above the first vertical stack in the Z direction, each channel electrically coupling the third S/D region to the fourth S/D region through the second GAA region and being separated from the second GAA region by a second dielectric material.

4. The semiconductor structure of claim 1, wherein the vertical connector provides a first voltage from the one of the plurality of BM conductors to the third S/D region, the fourth S/D region, or the second gate.

5. The semiconductor structure of claim 1, wherein the vertical connector comprises a trench via extending in the X direction.

6. The semiconductor structure of claim 1, wherein the vertical connector extends in the Z direction at least from a bottom surface of the first gate to a top surface of the second gate.

7. The semiconductor structure of claim 1, further comprising a second vertical connector that electrically couples the second S/D region to the fourth S/D region by direct contact with both the second S/D region and the fourth S/D region.

8. The semiconductor structure of claim 7, wherein the second vertical connector is electrically coupled to one of the plurality of FM conductors, another of the plurality of BM conductors, or both.

9. The semiconductor structure of claim 1, further comprising a backside jumper (BSJ), disposed below the first gate and isolated from the first gate by a dielectric material, that electrically couples the first S/D region to the second S/D region.

10. The semiconductor structure of claim 9, wherein the BSJ is electrically connected to another of the plurality of BM conductors.

11. The semiconductor structure of claim 1, wherein the semiconductor structure comprises a standard cell.

12. The semiconductor structure of claim 11, wherein the plurality of FM conductors extending in the X direction consists of four or fewer FM conductors extending in the X direction.

13. The semiconductor structure of claim 11, wherein the plurality of BM conductors extending in the X direction consists of four or fewer BM conductors extending in the X direction.

14. The semiconductor structure of claim 11, wherein the plurality of FM conductors extending in the X direction consists of three or fewer FM conductors extending in the X direction.

15. The semiconductor structure of claim 11, wherein the plurality of BM conductors extending in the X direction consists of three or fewer BM conductors extending in the X direction.

16. A method of fabricating a semiconductor structure, the method comprising:
providing a first field effect transistor (FET) of a first charge carrier type, comprising a first source/drain (S/D) region, a second S/D region, and a first gate;
providing a second FET of a second charge carrier type, disposed above the first FET in a Z direction and comprising a third S/D region, a fourth S/D region, and a second gate;
providing a frontside (FS) metal (FM) layer disposed above the second FET in the Z direction and comprising a plurality of FM conductors extending in an X direction and spaced apart from each other in a Y direction;
providing a backside (BS) metal (BM) layer disposed below the first FET in the Z direction and comprising a plurality of BM conductors extending in the X direction and spaced apart from each other in the Y direction; and
providing a vertical connector extending in the Z direction, wherein the vertical connector electrically couples one of the plurality of BM conductors to the third S/D region, the fourth S/D region, or the second gate.

17. The method of claim 16, wherein providing the first FET comprises providing a gate-all-around (GAA) FET comprising a first GAA region and wherein providing the second FET comprises providing a GAA FET comprising a second GAA region.

18. The method of claim 17, wherein:
providing the first FET comprises providing a first plurality of nanosheet channels extending in the X direction and spaced apart from each other in the Z direction to from a first vertical stack, each channel electrically coupling the first S/D region to the second S/D region through the first GAA region and being separated from the first GAA region by a first dielectric material; and
providing the second FET comprises providing a plurality of nanosheet channels extending in the X direction and spaced apart from each other in the Z direction to from a second vertical stack disposed above the first vertical stack in the Z direction, each channel electrically coupling the third S/D region to the fourth S/D region through the second GAA region and being separated from the second GAA region by a second dielectric material.

19. The method of claim 16, wherein providing the vertical connector comprises providing the vertical connector as a trench via extending in the X direction.

20. The method of claim 16, wherein providing the vertical connector comprises providing a vertical connector that extends in the Z direction at least from a bottom surface of the first gate to a top surface of the second gate.

21. The method of claim 16, further comprising providing a second vertical connector that electrically couples the second S/D region to the fourth S/D region by direct contact with both the second S/D region and the fourth S/D region.

22. The method of claim 21, further comprising electrically coupling the second vertical connector to one of the plurality of FM conductors, another of the plurality of BM conductors, or both.

23. The method of claim 16, further comprising providing a backside jumper (BSJ), disposed below the first gate and isolated from the first gate by a dielectric material, that electrically couples the first S/D region to the second S/D region.

24. The method of claim 23, further comprising electrically coupling the BSJ to another of the plurality of BM conductors.

25. The method of claim 16, wherein the plurality of FM conductors extending in the X direction consists of four or fewer FM conductors extending in the X direction.

26. The method of claim 16, wherein the plurality of BM conductors extending in the X direction consists of four or fewer BM conductors extending in the X direction.

27. The method of claim 16, wherein the plurality of FM conductors extending in the X direction consists of three or fewer FM conductors extending in the X direction.

28. The method of claim 16, wherein the plurality of BM conductors extending in the X direction consists of three or fewer BM conductors extending in the X direction.
